(19) United States
(12) Patent Application Publication
(10) Pub. No.: US 2011/0061922 A1
(43) Pub. Date: Mar. 17, 2011

(54) PACKAGE SUBSTRATE AND METHOD OF FABRICATING THE SAME

(76) Inventors: Jae Joon LEE, Gyunggi-do (KR); Jin Yong Ahn, Gyunggi-do (KR); Jin Ho Kim, Gyunggi-do (KR); Dong Ju Jeon, Seoul (KR)

(21) Appl. No.: 12/610,166

(22) Filed: Oct. 30, 2009

(30) Foreign Application Priority Data
Sep. 17, 2009 (KR) 10-2009-0088149

(51) Int. Cl. H05K 1/11; H05K 3/10

(52) U.S. Cl. 174/261; 29/846

(57) ABSTRACT

Disclosed is a package substrate, which includes an insulating layer including a circuit layer having a via for connecting layers and an insulating member formed in the insulating layer so as to separate the insulating layer, thus preventing the package substrate from warping and reducing land co-planarity of the substrate. A method of fabricating the package substrate is also provided, including (a) forming a first circuit layer on a carrier, (b) forming an insulating layer on the carrier having the first circuit layer, (c) forming an insulating member in the insulating layer so as to separate the insulating layer, (d) forming a second circuit layer including a via on the insulating layer and the insulating member, and (e) removing the carrier.

### CROSS REFERENCE TO RELATED APPLICATION

This application claims the benefit of Korean Patent Application No. 10-2009-0088149, filed Sep. 17, 2009, entitled “Package substrate and method of fabricating the same”, which is hereby incorporated by reference in its entirety into this application.

### BACKGROUND OF THE INVENTION

1. Technical Field

The present invention relates to a package substrate and a method of fabricating the same.

2. Description of the Related Art

There is a need for a thin package substrate which is improved in terms of signal transmission speed because of increasing performance and decreasing size of electronic apparatuses. To satisfy the market requirements, a package substrate is evolving from a conventional core substrate into a coreless substrate which has been made thinner due to the removal of a core. The coreless thin package substrate may have a reduced loop inductance due to the low thickness thereof thereby greatly improving signal transmission speed.

Although the high-density coreless thin package substrate has improved electrical properties, as the thickness thereof becomes thinner, warpage of a final product occurs more increasingly than when a conventional core substrate is used.

Meanwhile, a package substrate is mounted on a mother board and thus performs its function as an electronic part. Such mounting requires that a primary mounting process for mounting a die on a package substrate and a secondary mounting process for mounting the package substrate on a mother board be carried out. For efficient primary and secondary mounting, the package substrate requires low land co-planarity of a die mounting region and low land co-planarity of the entire substrate.

The conventional coreless thin package substrate is manufactured by stacking circuit layers and insulating layers in alternation. The package substrate includes circuit layers having different copper contents and insulating layers in which vias are formed so as to connect the circuit layers to each other. The insulating layers are made of materials having the same mechanical properties (rigidity and coefficient of thermal expansion).

When the insulating layers having the same material properties are used, the entire package substrate may warp due to the effect of heat generated during the fabrication of the substrate. The warpage of the package substrate has an influence on land co-planarity of the die mounting region (C4 region) and land co-planarity of the entire substrate in a subsequent primary mounting process, thus making it difficult to perform die mounting. Accordingly, the secondary mounting process for mounting the die-mounted package substrate on a mother board is much more difficult to perform.

Furthermore, in the case where the package substrate has a multilayer structure, the above problems of the primary and secondary mounting processes become more serious attributable to the coefficients of thermal expansion of respective layers being mismatched.

The degree of warpage of the package substrate increases from a center of the substrate toward edges thereof in a transverse or longitudinal direction, and is the greatest at the corners of the package substrate where warpage in a transverse direction and warpage in a longitudinal direction come together.

As mentioned above, the coreless thin package substrate is sensitive to heat because of its structure thereby making it difficult to control land co-planarity of the substrate. In the case where the substrate warps, the yield of primary mounting is decreased, and the yield of secondary mounting is also decreased. Hence, even after the package substrate is produced, defective rates may be remarkably increased during the fabrication of a final product.

### SUMMARY OF THE INVENTION

Accordingly, the present invention has been made keeping in mind the problems encountered in the related art and the present invention is intended to provide a package substrate which includes an insulating layer and an insulating member which is formed in the insulating layer and has a low coefficient of thermal expansion, wherein the insulating member separates the insulating layer.

Also the present invention is intended to provide a package substrate which includes an insulating layer and an insulation member patterned in a closed loop shape or a line shape in the insulating layer, so that both a die mounting region and the entire substrate have low land co-planarity.

Also the present invention is intended to provide a method of fabricating the package substrate.

An aspect of the present invention provides a package substrate, including an insulating layer including a circuit layer having a via for connecting layers, and an insulating member formed in the insulating layer so as to separate the insulating layer.

In this aspect, the insulating member may be formed of a material having a coefficient of thermal expansion lower than that of the insulating layer.

In this aspect, the insulating member may be formed in a thickness direction of the insulating layer, and may have a closed loop shape when viewed from above.

In this aspect, the insulating member in a closed loop shape when viewed from above may be provided in a plural number.

In this aspect, the closed loop shape may be circular or quadrangular.

In this aspect, the insulating member may be formed so as to include a die mounting region therein.

In this aspect, the insulating layer may have a multilayer structure.

In this aspect, the insulating member may be formed in a thickness direction of the insulating layer, and may have a line shape when viewed from above.

In this aspect, the insulating member in a line shape when viewed from above may be provided in a plural number.

In this aspect, the line shape may be formed in either a transverse direction or a longitudinal direction.

In this aspect, the line shape may be formed in both a transverse direction and a longitudinal direction, thus forming a closed line around the die mounting region.

In this aspect, one or more assistant insulating members in a closed loop shape may be further provided around the closed line.

In this aspect, the closed loop shape may be circular or quadrangular.

Another aspect of the present invention provides a method of fabricating the package substrate, including (a) forming a first circuit layer on a carrier, (b) forming an insulating layer on the carrier having the first circuit layer, (c) forming an insulating member in the insulating layer so as to separate the insulating layer, (d) forming a second circuit layer including a via on the insulating layer and the insulating member, and (e) removing the carrier.

In this aspect, the method may further include (f) forming a passivation layer on either or both surfaces of the first circuit layer and the second circuit layer, after (e).

In this aspect, (b) may be performed by using an insulating layer having a trench formed in a thickness direction, and (c) is performed by charging the insulating member in the trench of the insulating layer.

In this aspect, (b) may be performed by using an insulating layer in a semi-cured state, and (c) is performed by incorporating the insulating member in the insulating layer.

In this aspect, (c) may be performed by forming a trench in the insulating layer, and charging the insulating member in the trench of the insulating layer.

A further aspect of the present invention provides a method of fabricating the package substrate, including (a) forming a first circuit layer on a carrier, (b) forming an insulating member on the carrier having the first circuit layer, (c) forming an insulating layer on the carrier having the insulating member so that the insulating member is incorporated in the insulating layer to thus separate the insulating layer, (d) forming a second circuit layer including a via on the insulating layer and the insulating member, and (e) removing the carrier.

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing a package substrate according to an embodiment of the present invention;

FIG. 2 is a top plan view showing a package substrate according to another embodiment of the present invention;

FIG. 3 is a top plan view showing a package substrate according to still another embodiment of the present invention;

FIG. 4 shows results of simulation of land co-planarity of a conventional package substrate;

FIG. 5 shows results of simulation of land co-planarity of the package substrate according to the embodiment of the present invention;

FIGS. 6 to 11 are cross-sectional views sequentially showing a process of fabricating a package substrate according to a first embodiment of the present invention;

FIGS. 12 to 16 are cross-sectional views sequentially showing a process of fabricating a package substrate according to a second embodiment of the present invention;

FIGS. 17 to 21 are cross-sectional views sequentially showing a process of fabricating a package substrate according to a third embodiment of the present invention; and

FIGS. 22 to 26 are cross-sectional views sequentially showing a process of fabricating a package substrate according to a fourth embodiment of the present invention.

### DESCRIPTION OF SPECIFIC EMBODIMENTS

Hereinafter, embodiments of the present invention will be described in detail while referring to the accompanying drawings. Throughout the drawings, the same reference numerals refer to the same or similar elements. Also, redundant descriptions will be omitted. Furthermore, descriptions of known techniques, even if they are pertinent to the present invention, are regarded as unnecessary and may be omitted in so far as they would make the characteristics of the invention unclear and muddy the description.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

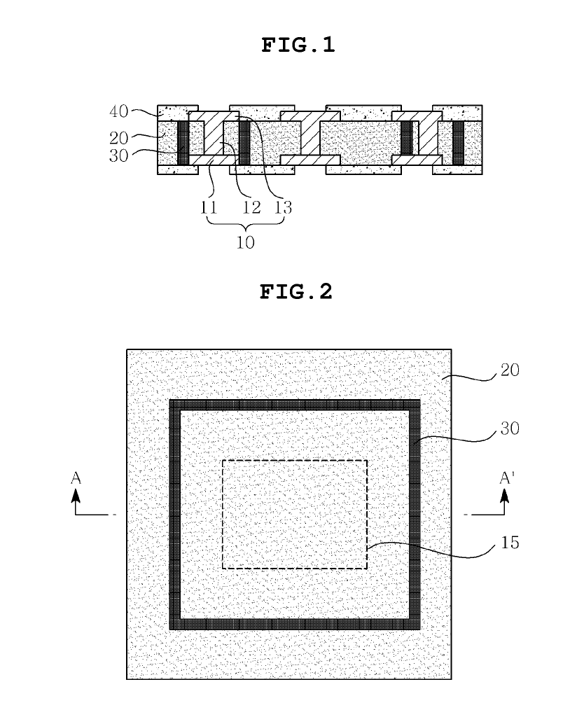

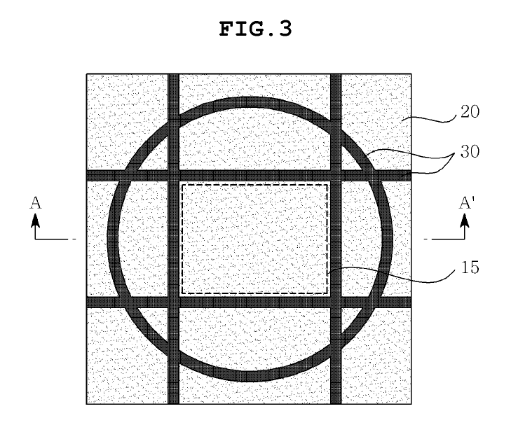

FIG. 1 is a cross-sectional view showing a package substrate according to an embodiment of the present invention, FIG. 2 is a top plan view showing a package substrate according to another embodiment of the present invention, and FIG. 3 is a top plan view showing a package substrate according to still another embodiment of the present invention. With reference to these drawings, the package substrate according to the embodiments of the present invention is described below.

As shown in FIG. 1, the package substrate according to the embodiment of the present invention includes an insulating layer 20 having a circuit layer 10, and an insulating member 30 formed in the insulating layer 20 so as to separate the insulating layer 20.

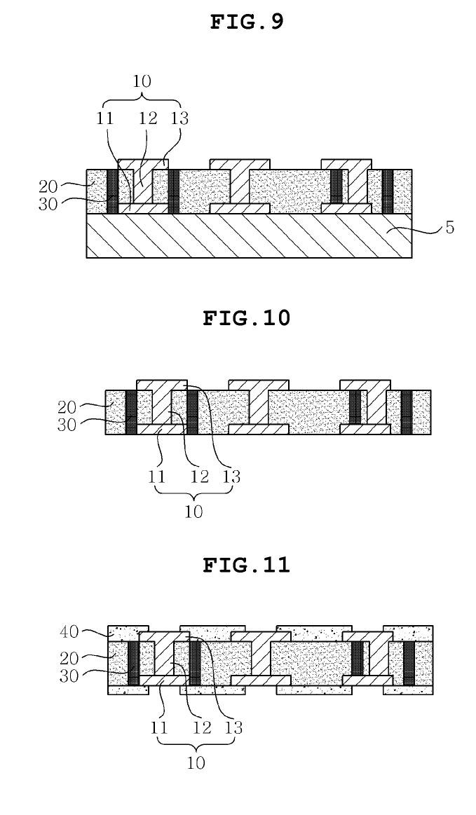

The circuit layer 10 which is a metal layer for transmitting an electrical signal includes a first circuit layer 11 formed on one surface of the insulating layer 20, and a second circuit layer 13 connected to the first circuit layer 11 using a via 12. The package substrate includes a die mounted on one surface thereof, and is mounted to a mother board at the other surface of the package substrate. The first circuit layer 11 and the second circuit layer 13 include a connection pad to which a solder ball is connected upon primary mounting and secondary mounting and a circuit pattern for transmitting a signal. The shape of the circuit layer 10 shown in FIG. 9 is merely illustrative.

The insulating layer 20, which forms a volume of the substrate, functions to protect the circuit layer 10 and to separate the adjacent circuit layers from each other. The insulating layer 20 is made of a plastic resin such as a thermosetting resin or a thermoplastic resin, and may further include a reinforcement such as glass fiber, glass non-woven fabric or the like.

The insulating layer 20 of FIG. 1 is illustratively provided in the form of a monolayer, or alternatively may have a multilayer structure. The multilayer structure may be formed by stacking one or more insulating layers having circuit layers on the insulating layer 20 having the circuit layer 10. A two-, three- or four-layer structure may be formed depending on the number of insulating layers. As the number of stacked layers increases, the total thickness of the package substrate increases.

The insulating member 30 is formed in the insulating layer 2 so as to separate the insulating layer 20. The package substrate composed basically of the circuit layer 10 and the insulating layer 20 has improved electrical properties but may undesirably warp due to the low thickness thereof. In order to mount a die on the package substrate (primary mounting) and mount the die-mounted package substrate on a mother board (secondary mounting), the die mounting region of the package substrate and the entire package substrate should have low land co-planarity. The warpage of the substrate may undesirably cause problems upon primary mounting and secondary mounting.

The insulating member 30 is formed in the insulating layer 20 to thus spatially separate the insulating layer 20. Because the warpage of the substrate may occur continuously over the entire substrate, the insulating member 30 formed in the insulating layer 20 plays a role in interrupting such continuous warpage. Hence, the warpage of the substrate may be divided into warpage segments which are decreased in size as a function of the number of insulating members 30, thus further reducing the co-planarity of the substrate.

The insulating member 30 may be formed of a material having a coefficient of thermal expansion lower than that of the insulating layer 20, in particular, a heterogeneous material having a low coefficient of thermal expansion. In the course of primary mounting, secondary mounting or other fabrication procedures, heat may be applied differently to one surface and to the other surface of the package substrate. Accordingly, when one surface and the other surface of the package substrate which is sensitive to heat expand at different rates, the substrate may undesirably warp.

As shown in FIG. 1, the insulating member 30 having a low coefficient of thermal expansion may be formed in the insulating layer 20 at a position located in a thickness direction of the insulating layer 20. When heat applied to one surface of the substrate is absorbed and then gets transferred to the other surface thereof, the insulating member 30 with the lower coefficient of thermal expansion expands comparatively less than the insulating layer 20, thereby reducing the expansion rate of one surface of the substrate and preventing the substrate from warping as a result of unbalanced expansion between one surface of the substrate and the other surface thereof.

Although FIG. 1 illustrates the insulating member 30 which is formed to pass through the total thickness of the insulating layer 20, the insulating member 30 may be partially formed to pass through a region of the insulating layer 20 ranging from one surface of the insulating layer to the center thereof. The insulating member 30 may be formed only at a portion where the circuit layer is not located so as not to affect the circuit layer 10 formed on the insulating layer 20.

Also, the insulating member 30 is formed in a thickness direction of the insulating layer as stated above, and may have a closed loop shape when viewed from above. This is specified below with reference to FIG. 2 in which the circuit layer is omitted for the sake of illustration.

When the insulating member 30 has a closed loop shape, the insulating layer 20 is separated into an inner region and an outer region inside and outside the closed loop, and continuous warpage of the substrate may be interrupted by the closed loop. When seen from the cross-sectional direction (A-A′), in the case where a single insulating member 30 in a closed loop shape is formed, continuous warpage in the direction A-A′ may be divided at two points, thus forming three separate warpage segments. Consequently, the land co-planarity of the substrate may be reduced.

Furthermore, a plurality of insulating members 30 in a closed loop shape when viewed from above may be provided. The use of the plurality of insulating members in a closed loop shape enables the insulating layer 20 to be separated into more regions so that warpage of the substrate may be divided into more warpage segments. For example, two insulating members in a closed loop shape may divide continuous warpage at four points thus forming five separate warpage segments.

The closed loop shape of the insulating member 30 may be quadrangular or circular. FIG. 2 illustrates a single insulating member 30 in a quadrangular closed loop shape when viewed from above. Generally the degree of warpage of the package substrate increases toward the edges or corners of the package substrate. As shown in FIG. 2, when the insulating member 30 is provided in a quadrangular shape at the middle between the die mounting region 15 and the edges of the substrate, the warpage of the entire substrate may be uniformly divided. Specifically, when the corners of the insulating member 30 are located at the middle between the die mounting region 15 and the corners of the substrate and also when the edges of the insulating member 30 are located at the middle between the die mounting region 15 and the edges of the substrate, the insulating member 30 is located at the middle between the die mounting region 15 and the edges of the substrate. Thus, as the ratio of the distance between the die mounting region 15 and the insulating member 30 and the distance between the insulating member 30 and the edges of the substrate becomes uniform, the warpage of the substrate may be uniformly divided.

In addition, a circular closed loop of the insulating member 30 may uniformly divide the warpage of the entire substrate, and also, the warpage of the substrate may be divided in circular form, thus changing the direction of the warpage.

The insulating member 30 in a closed loop shape may be formed to include the die mounting region 15 therein when viewed from above. As such, in the case where the substrate includes a plurality of insulating members 30 in a closed loop shape, it is desirable to enclose the die mounting region with the innermost insulating member 30. The die mounting region 15 which is a region where a die is mounted on the package substrate through primary mounting may include a plurality of connection pads and thus require rigidity. Hence, in order to reduce land co-planarity of the substrate and to maintain rigidity of the die mounting region 15, it is desirable that the insulating member 30 is not formed in the die mounting region 15.

With reference to FIG. 3, a package substrate according to still another embodiment of the present invention is described below. The description for the same elements as those of the package substrate described with reference to FIGS. 1 and 2 is omitted.

As shown in FIG. 3, the package substrate according to the present embodiment is configured such that an insulating member 30 is formed in a thickness direction of an insulating layer and has a line shape when viewed from above.

The insulating member 30 in a line shape separates the insulating layer 20 into two from one side to the other side, and may also divide the warpage of the substrate into two. Thus, the use of a plurality of insulating members in a line shape enables the warpage of the substrate to be divided into more warpage segments and thus is desirable in terms of reducing warpage.

The insulating member 30 in a line shape may be formed in either a transverse direction or a longitudinal direction. In the case where the plurality of insulating members 30 in a line shape is formed in either a transverse direction or a longitudinal direction, respective insulating members 30 in a line shape may be formed parallel to the insulating members 30 in a line shape adjacent thereto. If so, the warpage of the substrate may be uniformly divided.

As also shown in FIG. 3, the insulating members 30 in a line shape may be formed in both a transverse direction and a longitudinal direction, thus defining a closed line around the die mounting region. This closed line is additionally defined by forming the insulating members 30 in a line shape in both a transverse direction and a longitudinal direction, unlike the closed loop structure of FIG. 2.

Such a line shape may divide the warpage of the substrate into warpage segments which are decreased in size in each of a transverse direction and a longitudinal direction. Moreover, when two insulating members 30 in a transverse direction and two insulating members 30 in a longitudinal direction are formed together to thus define a closed line around the die mounting region 15, warpage may be divided into warpage segments which are decreased in size in the transverse and longitudinal directions, and simultaneously, rigidity of the die mounting region 15 may be ensured.

As shown in FIG. 3, an assistant insulating member 30 in a closed loop shape may be further provided. The assistant insulating member 30 in a closed loop shape may divide warpage of the substrate into more warpage segments and allows the direction of divided warpage to be guided in a closed loop shape. Hence, the closed loop shape of the assistant insulating member 30 may be quadrangular or circular. The assistant insulating member 30 having such a closed loop shape may reduce warpage occurring at edges of the substrate as described with reference to FIG. 1.

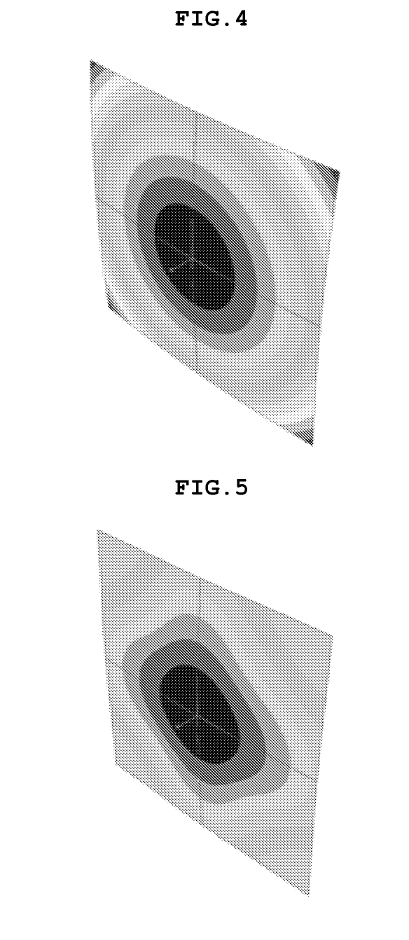

The warpage reducing effect according to the present embodiment is described below with reference to FIGS. 4 and 5. FIG. 4 shows results of simulation of land co-planarity of a conventional package substrate, and FIG. 5 shows results of simulation of land co-planarity of the package substrate according to the present embodiment, as shown in FIG. 3, in which two insulating members 30 in a transverse direction and two insulating members 30 in a longitudinal direction may be formed together thus defining a closed line around the die mounting region 15 and also which further includes an assistant insulating member 30 in a circular closed loop shape formed around the die mounting region 15.

As is apparent from results of simulation, the land co-planarity of the package substrate according to the present embodiment was decreased by about 12% at the die mounting region and by about 42% at the other regions, compared to the conventional package substrate.

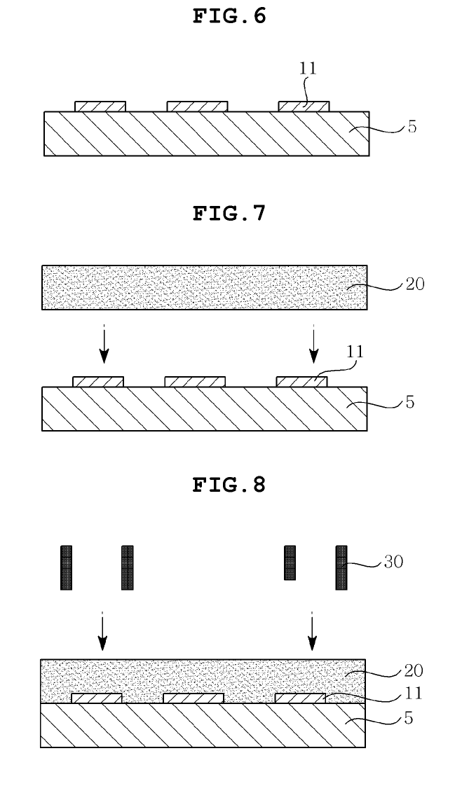

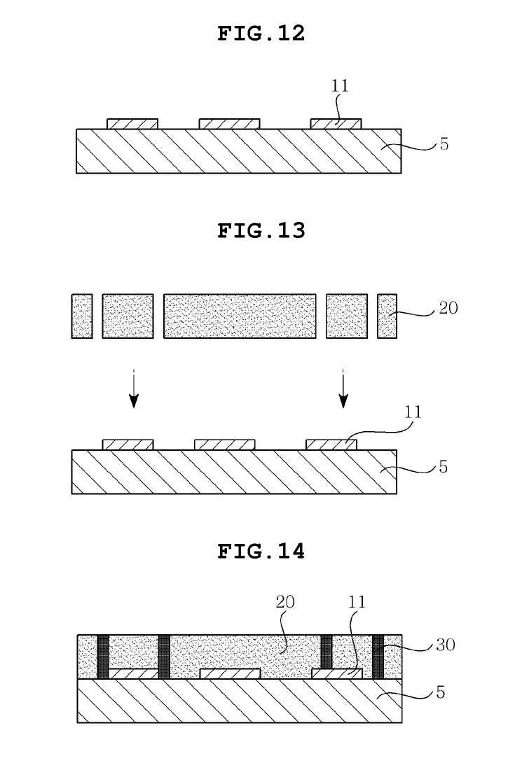

FIGS. 6 to 11 sequentially show a process of fabricating a package substrate according to a first embodiment of the present invention, FIGS. 12 to 16 sequentially show a process of fabricating a package substrate according to a second embodiment of the present invention, FIGS. 17 to 21 sequentially show a process of fabricating a package substrate according to a third embodiment of the present invention, and FIGS. 22 to 26 sequentially show a process of fabricating a package substrate according to a fourth embodiment of the present invention. Below, the method of fabricating the package substrate according to the embodiments of the present invention is described with reference to the above drawings.

With reference to FIGS. 6 to 11, the method of fabricating the package substrate according to the first embodiment of the present invention is specified below.

As shown in FIG. 6, a first circuit layer 11 is formed on a carrier 5.

Because problems may occur during the fabrication process of the package substrate attributable to the low thickness of the package substrate, the carrier 5 having predetermined rigidity is used to impart rigidity to the fabrication of the package substrate, thus increasing fabrication processability. The carrier 5 may be made of metal, synthetic plastic, etc. The carrier 5 is removed in a final procedure in the course of fabrication of the package substrate.

A first circuit layer 11 formed on the carrier 5 is made through a typical process such as copper plating or ink-jet printing. The circuit layer 11 includes a circuit pattern functioning as a pad connected by a solder ball upon primary mounting for mounting a die or secondary mounting for mounting the package substrate on a mother board.

Next, as shown in FIG. 7, an insulating layer 20 is formed on the carrier 5 having the first circuit layer 11.

The insulating layer 20 is formed on the carrier 5 so that the first circuit layer 11 is completely covered. To this end, a prepreg in a semi-cured state composed of glass fiber and a thermosetting resin may be applied. The insulating layer 20 supports the package substrate and insulates an area between the circuit layers.

The insulating layer 20 may be formed by applying a plastic resin on the carrier 5. The plastic resin may include for example a thermosetting resin, a thermoplastic resin, etc. The plastic resin may further include an additive, such as an assistant material such as glass fiber, a defoamer, a dispersant and so on. The material and configuration of the insulating layer are known and the specific description thereof is omitted.

As shown in FIG. 8, an insulating member 30 is formed in the insulating layer so as to separate the insulating layer 20.

The package substrate may warp due to different thermal expansion rates of the upper and lower surfaces thereof and due to heat and pressure during primary mounting and secondary mounting. With the goal of dividing the warpage of the substrate so as to reduce co-planarity of the substrate, the insulating member 30 may be formed in the insulating layer thus spatially separating the insulating layer 20.

As such, in order to separate the insulating layer 20, the insulating member 30 is incorporated in the insulating layer 20 in a semi-cured state. The insulating member 30 may be made of a heterogeneous plastic resin having a coefficient of thermal expansion lower than that of the plastic resin of the insulating layer 20. The insulating member 30 may have a closed loop shape or a line shape. The insulating member 30 having a preset shape is prepared and then incorporated in the insulating layer 20 in a semi-cured state.

Next, as shown in FIG. 9, a second circuit layer 13 having a via 12 is formed on the insulating layer 20 and the insulating member 30.

To form the via 12 for connecting the first circuit layer 11 formed on the carrier 5 to the second circuit layer which will be formed on the insulating layer 20, a via hole is formed in the insulating layer 20. As such, the via hole may be formed through mechanical drilling or laser drilling.

Then, the via hole may be subjected to electroless copper plating and copper electroplating thus forming the via 12, or alternatively the via hole 12 may be filled with a copper plating solution thus forming the via 12. Subsequently, the second circuit layer 13 is formed on the insulating layer 20. The second circuit layer 13 may also perform the same function as that of the first circuit layer 11.

Next, as shown in FIG. 10, the carrier 5 is removed. The carrier is used to ensure fabrication processability of a package substrate, and is removed after completion of fabrication of the package substrate, so that the thickness of the package substrate may be maintained thinner. Even when the package substrate is thin, the insulating member 30 may suppress the warping of the package substrate.

Next, as shown in FIG. 11, formation of a passivation layer 40 on either or both surfaces of the package substrate having the first circuit layer 11 and the second circuit layer 13 may be further conducted.

Because the first circuit layer 11 and the second circuit layer 13 are exposed outside of the insulating layer, they may undergo contact with impurities, physical damage or oxidation. Hence, the passivation layer 40 is formed on the first circuit layer 11 and the second circuit layer 13. As such, the passivation layer 40 may be formed to expose a contact pad (a circuit pattern connected to a solder ball).

The passivation layer 40 may be formed using a solder resist. The solder resist may be formed through screen printing, roller coating, curtain coating, or spray coating. Thereafter exposure and development are performed, thus exposing the contact pad.

The insulating layer 20 of the package substrate may be manufactured to have a multilayer structure. The package substrate with reference to FIG. 9 may be subjected to additional procedures including forming a second insulating layer on the insulating layer 20 having the second circuit layer 13, forming a second insulating member in the second insulating layer to separate the second insulating layer, and forming a third insulating layer having a via, thereby completing a package substrate having a two-layer structure.

When the above additional procedures are further performed once, the package substrate may have a three-layer structure. The package substrate may have a multilayer structure composed of more layers by further performing the additional procedures.

With reference to FIGS. 12 to 16, the method of fabricating the package substrate according to the second embodiment of the present invention is described below.

As shown in FIG. 12, a first circuit layer 11 is formed on a carrier 5. This is performed through the same procedure as the procedure described with reference to FIG. 6.

Next, as shown in FIG. 13, an insulating layer 20 having a trench formed in a thickness direction is formed on the carrier 5 having the first circuit layer 11. The trench may be processed using a laser, for example, Nd:YAG (Neodymium-doped Yttrium Aluminum Garnet) laser or pulsed UV (ultra-violet) excimer laser.

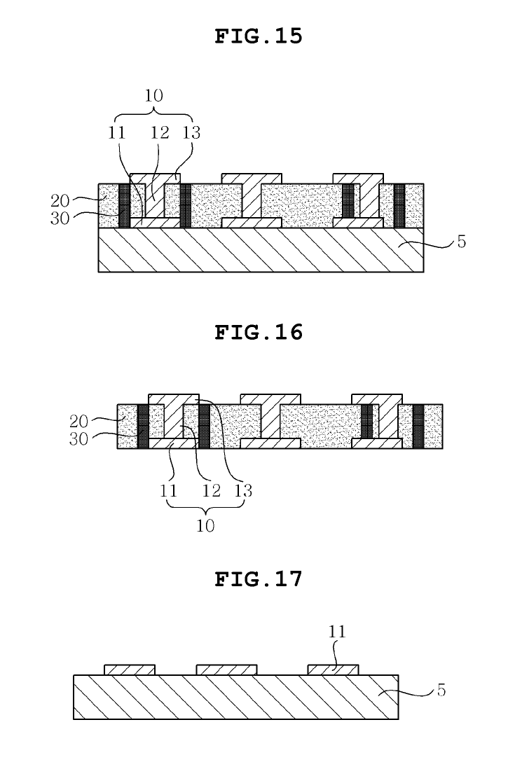

Next, as shown in FIG. 14, an insulating member 30 is charged in the trench of the insulating layer, thus separating the insulating layer 20. Next, as shown in FIG. 15, a second circuit layer 13 having a via 12 is formed on the insulating layer 20 and the insulating member 30, after which the carrier 5 is removed as shown in FIG. 16.

With reference to FIGS. 17 to 21, the method of fabricating the package substrate according to the third embodiment of the present invention is described below. The detailed description for the same procedures in the fabrication of the package substrate according to the first embodiment referring to FIGS. 6 to 11 and the second embodiment referring to FIGS. 12 to 16 is omitted.

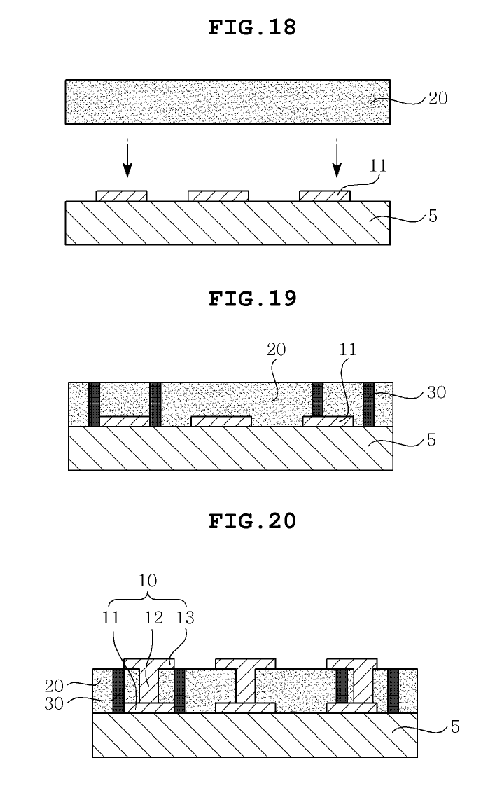

First, as shown in FIG. 17, a first circuit layer 11 is formed on a carrier 5. Next, as shown in FIG. 18, an insulating layer 20 is formed on the carrier 5 having the first circuit layer 11.

Next, as shown in FIG. 19, a trench is formed in the insulating layer 20 formed on the carrier 5. Because the insulating layer 20 is formed in a semi-cured state on the carrier 5, the formation of the trench after the curing of the insulating layer 20 is desirable. The trench may be formed using a laser as mentioned above, and the depth thereof may be adjusted.

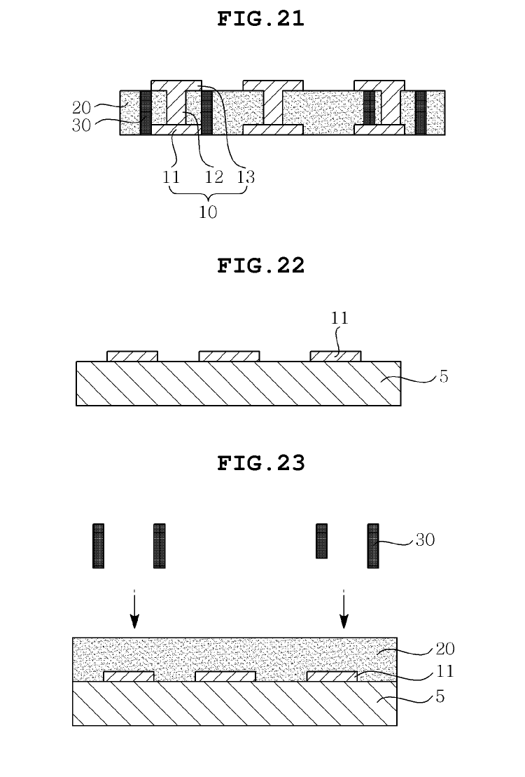

Next, as shown in FIG. 20, an insulating member 30 is charged in the trench of the insulating layer so as to separate the insulating layer 20. Next, a second circuit layer 13 having a via 12 is formed on the insulating layer 20 and the insulating member 30. As shown in FIG. 21, the carrier 5 is removed.

With reference to FIGS. 22 to 26, the method of fabricating the package substrate according to the fourth embodiment of the present invention is described below.

First, as shown in FIG. 22, a first circuit layer 11 is formed on a carrier 5. This procedure is the same as in the description with reference to FIG. 6, and the detailed description thereof is omitted.

Next, as shown in FIG. 23, an insulating member 30 is formed on the carrier 5 having the first circuit layer 11. The insulating member 30 may have a closed loop shape or a line shape.

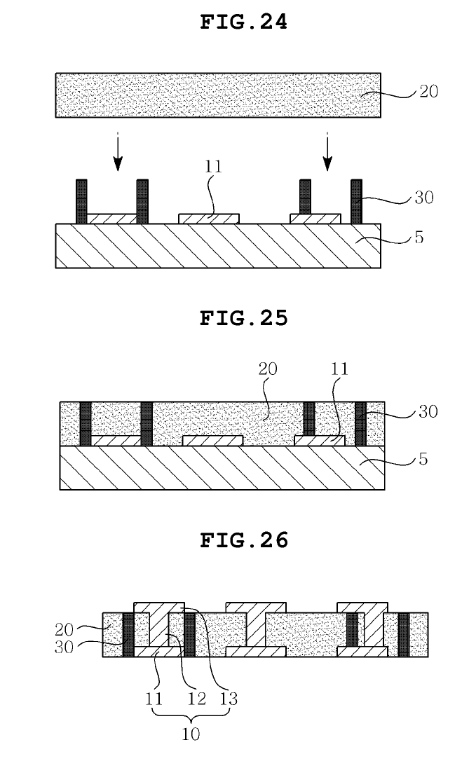

Next, as shown in FIG. 24, an insulating layer 20 is formed on the carrier 5 having the insulating member 30. As such, the insulating layer 20 is spatially separated due to the incorporation of the insulating member 30. For example, the use of a plastic resin in a semi-cured state such as a prepreg is desirable.

Next, as shown in FIG. 25, a second circuit layer 13 having a via 12 is formed on the insulating layer 20 and the insulating member 30, after which the carrier 5 is removed, as shown in FIG. 26.

As described hereinbefore, the present invention provides a package substrate and a method of fabricating the same. According to the present invention, an insulating member is formed in an insulating layer so as to separate the insulating layer, thus dividing warpage of the package substrate, thereby reducing land co-planarity of a die mounting region of the substrate and land co-planarity of the entire substrate.

Also, according to the present invention, the insulating member having a coefficient of thermal expansion lower than that of the insulating layer is formed in the insulating layer at a position located in a thickness direction of the insulating layer, so that thermal expansion rates of one surface of the insulating layer and the other surface thereof are made similar to each other, thus preventing the substrate from warping, thereby reducing land co-planarity of the die mounting region of the substrate and land co-planarity of the entire substrate.

Therefore, defective rates of primary mounting and secondary mounting of the package substrate can be decreased. Furthermore, land co-planarity of the die mounting region can be reduced, and thus stress occurring at the connected portion between the die and the substrate can be relieved, thereby prolonging the lifespan of the package substrate.

Although the embodiments of the present invention have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A package substrate, comprising:
an insulating layer including a circuit layer having a via for connecting layers; and
an insulating member formed in the insulating layer so as to separate the insulating layer.

2. The package substrate as set forth in claim 1, wherein the insulating member is formed of a material having a coefficient of thermal expansion lower than that of the insulating layer.

3. The package substrate as set forth in claim 1, wherein the insulating member is formed in a thickness direction of the insulating layer, and has a closed loop shape when viewed from above.

4. The package substrate as set forth in claim 3, wherein the insulating member in a closed loop shape when viewed from above is provided in a plural number.

5. The package substrate as set forth in claim 3, wherein the closed loop shape is circular or quadrangular.

6. The package substrate as set forth in claim 3, wherein the insulating member is formed so as to include a die mounting region therein.

7. The package substrate as set forth in claim 3, wherein the insulating layer has a multilayer structure.

8. The package substrate as set forth in claim 1, wherein the insulating member is formed in a thickness direction of the insulating layer, and has a line shape when viewed from above.

9. The package substrate as set forth in claim 8, wherein the insulating member in a line shape when viewed from above is provided in a plural number.

10. The package substrate as set forth in claim 8, wherein the line shape is formed in either a transverse direction or a longitudinal direction.

11. The package substrate as set forth in claim 8, wherein the line shape is formed in both a transverse direction and a longitudinal direction, thus forming a closed line around the die mounting region.

12. The package substrate as set forth in claim 8, wherein one or more assistant insulating members in a closed loop shape are further provided around the closed line.

13. The package substrate as set forth in claim 12, wherein the closed loop shape is circular or quadrangular.

14. A method of fabricating a package substrate, comprising:
(a) forming a first circuit layer on a carrier;
(b) forming an insulating layer on the carrier having the first circuit layer;
(c) forming an insulating member in the insulating layer so as to separate the insulating layer;
(d) forming a second circuit layer including a via on the insulating layer and the insulating member; and
(e) removing the carrier.

15. The method as set forth in claim 14, further comprising (f) forming a passivation layer on either or both surfaces of the first circuit layer and the second circuit layer, after (e).

16. The method as set forth in claim 14, wherein (b) is performed by using an insulating layer in a semi-cured state, and (c) is performed by incorporating the insulating member in the insulating layer.

17. The method as set forth in claim 14, wherein (b) is performed by using an insulating layer having a trench formed in a thickness direction, and (c) is performed by charging the insulating member in the trench of the insulating layer.

18. The method as set forth in claim 14, wherein (c) is performed by forming a trench in the insulating layer, and charging the insulating member in the trench of the insulating layer.

19. A method of fabricating a package substrate, comprising:
(a) forming a first circuit layer on a carrier;
(b) forming an insulating member on the carrier having the first circuit layer;
(c) forming an insulating layer on the carrier having the insulating member so that the insulating member is incorporated in the insulating layer to thus separate the insulating layer;
(d) forming a second circuit layer including a via on the insulating layer and the insulating member; and
(e) removing the carrier.
